(19) United States
(12) Patent Application Publication
(10) Pub. No.: US 2023/0301104 A1
(43) Pub. Date: Sep. 21, 2023

(54) THREE-DIMENSIONAL SEMICONDUCTOR DEVICE AND METHOD OF MANUFACTURING THE THREE-DIMENSIONAL SEMICONDUCTOR DEVICE

(71) Applicant: SK hynix Inc., Icheon-si Gyeonggi-do (KR)

(72) Inventors: Seung Min LEE, Icheon-si Gyeonggi-do (KR); Nam Kuk KIM, Icheon-si Gyeonggi-do (KR); Bo Yun KIM, Icheon-si Gyeonggi-do (KR); Jae Seok KIM, Icheon-si Gyeonggi-do (KR)

(73) Assignee: SK hynix Inc., Icheon-si Gyeonggi-do (KR)

(21) Appl. No.: 18/085,421

(22) Filed: Dec. 20, 2022

(30) Foreign Application Priority Data
Mar. 16, 2022 (KR) 10-2022-0032735

(51) Int. Cl. H10B 43/27

(52) U.S. Cl. CPC H01L 27/11582

(57) ABSTRACT

A three-dimeiisioiial semiconductor device including a memory block including a stack structure comprising a second sub stack formed over a first sub stack, a plurality of channel plugs formed through the stack structure, and a separation pattern formed in the memory block.

### CROSS-REFERENCES TO RELATED APPLICATION

The present application claims priority under 35 U.S.C. § 119(a) to Korean application number 10-2022-0032735, filed on Mar. 16, 2022, in the Korean Intellectual Property Office, which is incorporated herein by reference in its entirety.

### BACKGROUND

### 1. Technical Field

Various embodiments generally relate to a semiconductor device and a method of manufacturing the semiconductor device, and more particularly, to a three-dimensional semiconductor device and a method of manufacturing the three-dimensional semiconductor device.

### 2. Related Art

An integration density of a semiconductor device may be mainly determined by an occupying area of a memory cell. Recently, for increasing the integration density of the semiconductor device, a technique has been proposed in which the memory cell is formed in a three-dimensional structure. Further, a peripheral circuit may be arranged under at least one memory cell array including a plurality of memory cells.

### SUMMARY

According to various embodiments, there may be provided a three-dimensional (3D) semiconductor device. The 3D semiconductor device may include a memory block including a stack structure comprising a second sub stack formed over a first sub stack. The plurality of channel plugs is formed through the stack structure. The separation pattern is formed in the memory block. The separation pattern includes at least one of a plug type insulation pattern positioned in at least a portion of the first sub stack of the stack structure and at least one of a bar type insulation pattern positioned in at least a portion of the second sub stack of the stack structure.

According to various embodiments, there may be provided a method of manufacturing a 3D semiconductor device. In the method of manufacturing the 3D semiconductor device, a first stack structure including first insulation layers and first sacrificial layers alternately stacked may be formed. A cylindrical dummy plug may be formed through the first stack structure. A second stack structure including second insulation layers and second sacrificial layers alternately stacked may be formed on the first stack structure. Channel plugs may be formed through the first and second stack structures. The first and second stack structures may be etched to form a trench extended in a direction. The second stack structure may be etched to form an opening extended in the direction configured to expose the dummy plug. The dummy plug exposed through the opening may be remove4d to form a dummy hole. The first and second sacrificial layers exposed through the trench, the opening and the dummy hole may be removed to form gaps between first insulation layers and the second insulation layers. The gaps may be filled with conductive layers.

According to various embodiments, there may be provided a three-dimensional (3D) semiconductor device. The 3D semiconductor device may include a first sub stack including first conductive layers and first insulation layers alternately stacked in a vertical direction; a second sub stack including second conductive layers and second insulation layers alternately stacked on the first sub stack in the vertical direction; channel plugs formed through the first sub stack and the second sub stack; a plug type insulation pattern formed through the first sub stack between the channel plugs; and a bar type insulation pattern formed through the second sub stack to make contact with the plug type insulation pattern.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIGS. 1A and 1B are views illustrating a 3D semiconductor device in accordance with various embodiments.

FIGS. 2A, 2B, 3A, 3B, 4A, 4B, 5A, 5B, 6A, 6B, 7A, 7B, 8A, 8B, 9A, 9B, 10A, 10B, 11A, 11B, 12A, and 12B are views illustrating a method of manufacturing a 3D semiconductor device in accordance with various embodiments;

FIG. 13 is a block diagram illustrating a memory system in accordance with various embodiments;

FIG. 14 is a block diagram illustrating a memory system in accordance with various embodiments;

FIG. 15 is a block diagram illustrating a computing system in accordance with various embodiments; and

FIG. 16 is a block diagram illustrating a computing system in accordance with various embodiments.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The present disclosure is described herein with reference to cross-section and/or plan illustrations of idealized embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure. It will be understood that although the terms first, second, third etc. may be used herein to describe various elements, these elements should not be limited by these terms. These terms are only used to distinguish one element from another element, but not used to define only the element itself or to mean a particular sequence.

According to various embodiments, the sacrificial layer of the stack structure may be completely removed using a trench in a slit region and the dummy hole and the opening in a cell array region to improve characteristics and uniformity of a memory cell

Hereinafter, a 3D semiconductor device of various embodiments may be illustrated in detail with reference to accompanying drawings.

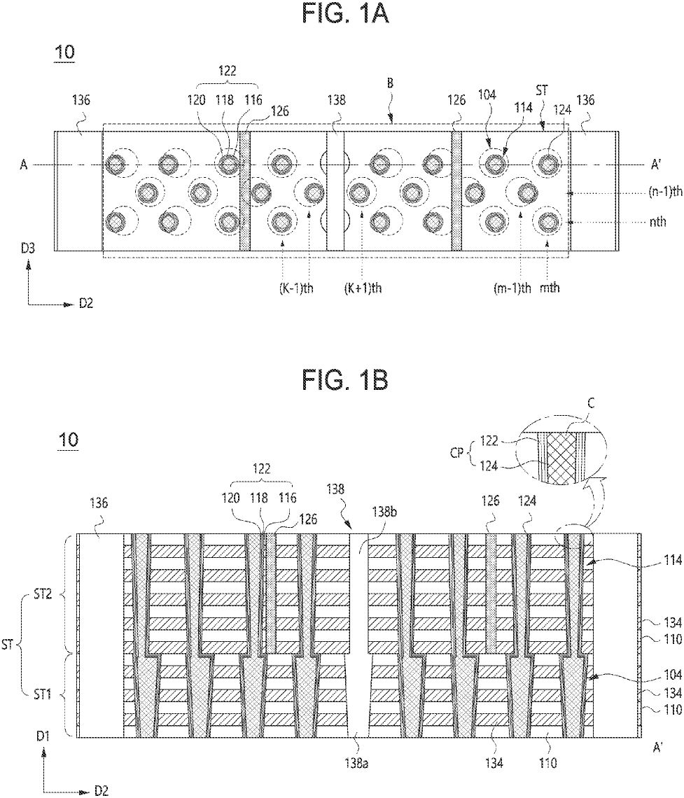

FIGS. 1A and 1B are views illustrating a 3D semiconductor device in accordance with various embodiments. FIG. 1A is a plan view illustrating the 3D semiconductor device. FIG. 1B is a cross-sectional view taken along a line A-A′ in FIG. 1A.

Referring to FIGS. 1A and 1B, a 3D semiconductor device 10 may include a stack structures ST, at least one slit structure 136, a plurality of channel plugs CP, a first separation pattern 126 and a second separation pattern 138.

The stack structure ST may include a first sub stack ST1 and a second sub stack ST2 which are sequentially and vertically stacked. For example, the stack structure ST may be located over a semiconductor substrate (not shown). The first sub stack ST1 and the second sub stack ST2 may include a plurality of conductive layers and a plurality of insulation layers, respectively. The conductive layers and the insulation layers may be alternately stacked in a vertical direction D1. In FIG. 1A and FIG. 1B, the vertical direction D1 may indicate a first direction corresponding to the vertical direction being perpendicular to an upper surface of the semiconductor substrate, a row direction D2 may indicate a second direction corresponding to a row direction and a column direction D3 may indicate a third direction corresponding to a column direction.

In various embodiments, the stack structure ST separated by the slit structure(s) 136 may correspond to a memory block of the three-dimensional(3D) semiconductor device. Each memory block may be the smallest unit that can be erased.

As an integration density of the three-dimensional (3D) semiconductor device increases, a height of the stack structure ST may be gradually increased. Due to the height of the stack structure ST, in some embodiments, it may be difficult to form holes penetrated through the stack structure ST using a single contact etching process. Thus, after forming the first sub stack ST1, first holes 104 may be formed through the first sub stack ST1. And then, after forming the second sub stack ST2, second holes 114 may be formed through the second sub stack ST2. Each of the second holes 114 may be partially overlapped with each of the first holes 104. Each of the first holes 104 may have a cylindrical shape having widths that decrease at corresponding greater depths within the stack structure ST or referred to herein as having a downwardly decreased width, due to a height of the first sub stack ST1. For example, each of the first holes 104 have a downwardly decreased width as shown in FIG. 1B. Each of the second holes 114 may also have a cylindrical shape having widths that decrease at corresponding greater depths within the stack structure ST or referred to herein as having a downwardly decreased width, due to a height of the second sub stack ST2. For example, each of the second holes 114 have a downwardly decreased width as shown in FIG. 1B. The first holes 104 and the second holes 114 may be corresponded to face each other, respectively. The corresponding first hole 104 and the second hole 114 facing each other may be connected.

Each of the channel plugs CP may be arranged entirely inside the corresponding first and second holes 104 and 114. Each of the channel plugs CP may include a memory layer 122 and a channel layer 124. The memory layer 122 may include a tunnel insulation layer 120, a data storage layer 118 and a charge blocking layer 116. The tunnel insulation layer 120 may be configured to surround the channel layer 124. The data storage layer 118 may be configured to surround the tunnel insulation layer 120. The charge blocking layer 116 may be configured to surround the data storage layer 118. In various embodiments, each of the channel plugs CP may further include a core layer C. For example, the core layer C may be configured in a form a pillar to fill most space of the first hole 104 and the second hole 114 and the channel layer 124 may be formed between the memory layer 120 and the core layer C. For example, the core layer C may include an insulation material such as oxide.

In various embodiments, the channel plugs CP may be arranged in a matrix having n rows (n is a natural number greater than2) and m columns (m is a natural number greater than 2). For example, the channel plugs CP in a (m-1)th column may be arranged between the adjacent two channel plugs CP in a (m)th column. Further, the channel plugs CP in a (n-1)th row may be arranged between the adjacent two channel plugs CP in a (n)th row.

The first separation pattern 126 may have a bar shape extended along the third direction D3 in a plan view. In various embodiments, the first separation pattern 126 may include two patterns, not limited thereto. The first separation patterns 126 may include an insulation material. Each of the first separation patterns 126 may be arranged at the first sub stack ST1. The first separation patterns 126 might not make contact with the channel plugs CP. However, the first separation patterns 126 might not be extended into the second sub stack ST2.

The second separation pattern 138 may have a bar shape extended along the third direction D3 in the plan view. The second separation pattern 138 may be arranged between portions of the slit structures 136 parallel to the third direction D3. The second separation pattern 138 may be formed through a central portion of the stack structure ST1 and ST2 in the plan view. Each of the first separation patterns 126 may be arranged between the slit structure 136 and the second separation pattern 138.

In various embodiments, the second separation pattern 138 may include an insulating material. The second separation pattern 138 may be arranged at a center column of the memory block B. The second separation pattern 138 may include at least one plug type insulation pattern 138a positioned in the first sub stack ST1 and a bar type insulation pattern 138b positioned in the second sub stack ST2. In an embodiment, the at least one plug type insulation pattern 138a may be positioned in a portion of the first sub stack ST1 and the bar type insulation pattern 138b may be positioned in a portion of the second sub stack ST2.

As mentioned above, the channel plugs CP may be arranged in the matrix having the n rows and the m columns. The second separation pattern 138 may have a shape incorporated into a part of the matrix including the n rows and the m columns. For example, when the second separation pattern 138 is arranged in a (k)th column (1<k<m, k is a natural number), the second separation pattern 138 may be arranged between the adjacent two channel plugs CP in a (k±1)th columns.

In an embodiment, openings (not shown) for forming the first separation patterns 126 and the second separation pattern 138 may be used as passages for forming gates (for example, a plurality of word lines, at least one drain selection line and at least one source selection line) of the memory block B. Particularly, in an embodiment, the openings for the first separation patterns 126 may be formed before the openings for the second separation pattern 138. In other words, in an embodiment, the first and second separation patterns 126 and 138 may be formed in the openings after the gates of the memory block B.

Hereinafter, a method of manufacturing a 3D semiconductor device in accordance with various embodiments may be illustrated with reference to drawings.

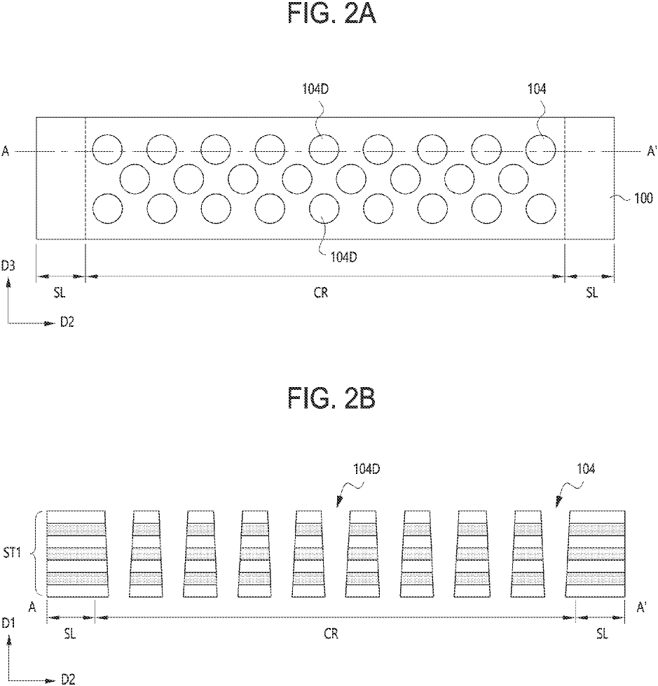

FIGS. 2A to 12A are plan views illustrating a method of manufacturing a 3D semiconductor device in accordance with various embodiments. FIGS. 2B to 12B are cross-sectional views taken along a line A-A′ in FIGS. 2A to 12A, respectively.

Referring to FIGS. 2A and 2B, first insulation layers 100 and first sacrificial layers 102 may be alternately stacked to form a first sub stack ST1. The first insulation layers 100 may include oxide, for example, a silicon oxide layer. The first sacrificial layers 102 may include a material having an etching selectivity with respect to an etchant for the first insulation layers 100. For example, the first sacrificial layers 102 may include nitride, for example, a silicon nitride layer.

The first sub stack ST1 may be formed over a cell array region CR and a slit region SL.

Selected portions of the first sub stack ST1 may be etched to form first holes 104 and 104D. For example, the first holes 104 and 104D may be formed in the cell array region CR. Each of first holes 104 and 104D may have a downwardly decreased diameter. An average of the downwardly decreased diameters may be a diameter of each of the first holes 104 and 104D. Each of the first holes 104 and 104D may have a first diameter. The reference numeral 104 may be a first hole 104 for forming a channel plug and the reference numeral 104D may be a first dummy hole for forming a dummy channel plug.

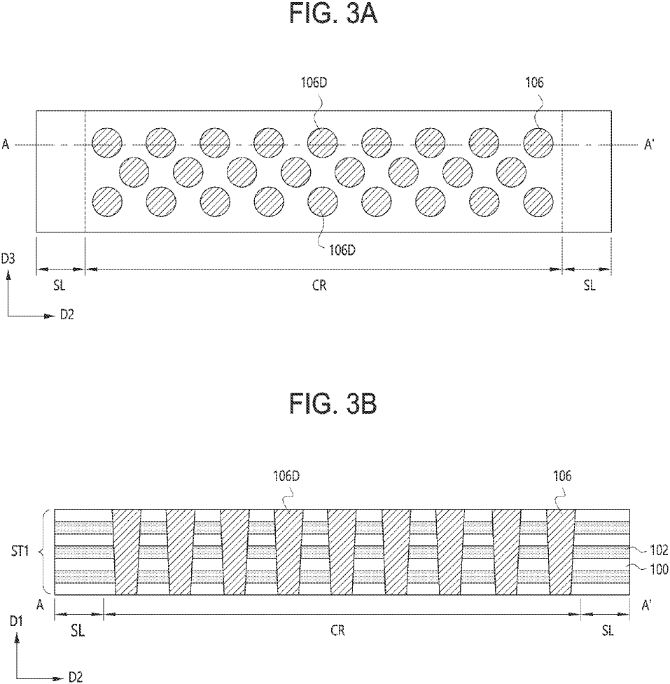

Referring to FIGS. 3A and 3B, the first holes 104 and the first dummy holes 104D may be filled with a conductive material to form first plugs 106 and dummy plugs 106D. The conductive material may have an etching selectivity with respect to an etchant for the first insulation layers 100 and the first sacrificial layers 102.

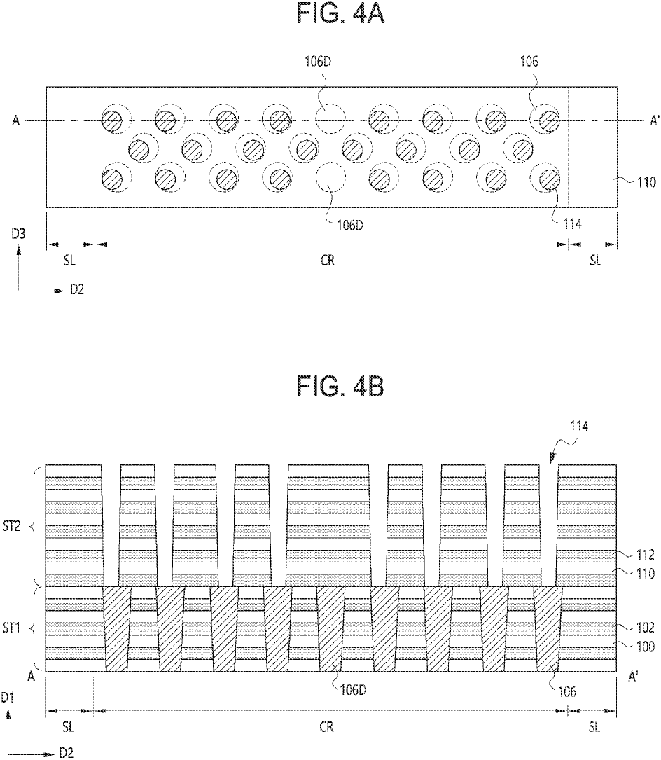

Referring to FIGS. 4A and 4B, second insulation layers 110 and second sacrificial layers 112 may be alternately stacked on the first sub stack ST1 to form a second sub stack ST2. The second insulation layers 110 may include a material substantially the same as a material of the first insulation layer 100, for example, the silicon oxide layer. The second sacrificial layers 112 may include a material substantially the same as a material of the first sacrificial layers 102, for example, the silicon nitride layer.

Selected portions of the second sub stack ST2 may be etched to form second holes 114. Each of the second holes 114 may be configured to expose the first plug 106. The first dummy plugs 106D are not exposed by the second holes 114. That is, the dummy plugs 106D may be covered by the second sub stack ST2.

Each of the second holes 114 may have a downwardly decreased diameter. An average of the downwardly decreased diameter may be a second diameter of the second hole 114. For example, the second diameter of the second hole 114 may be shorter than the first diameter of the first hole 104.

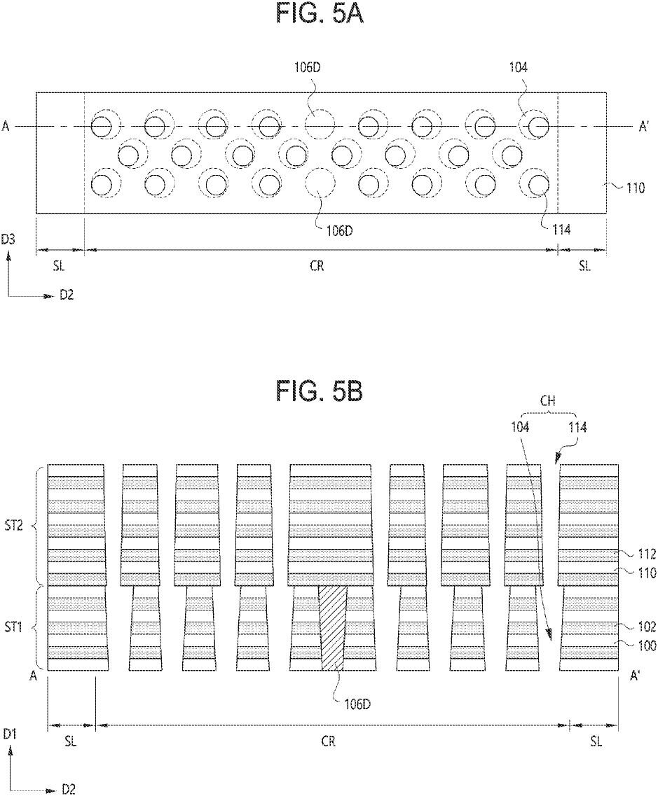

Referring to FIGS. 5A and 5B, the first plugs 106 exposed through the second holes 114 may be selectively removed to re-define the first holes 104 in the first sub stack ST1. Although the first plugs 106 are removed, the first dummy plug 106D is not removed, because the first dummy plug 106D is covered by the second sub stack ST2. Thus, the first holes 104 and the second holes 114 may be vertically connected, respectively. Hereinafter, the first hole 104 and the second hole 114 that connected with each other will be referred to as a channel hole CH.

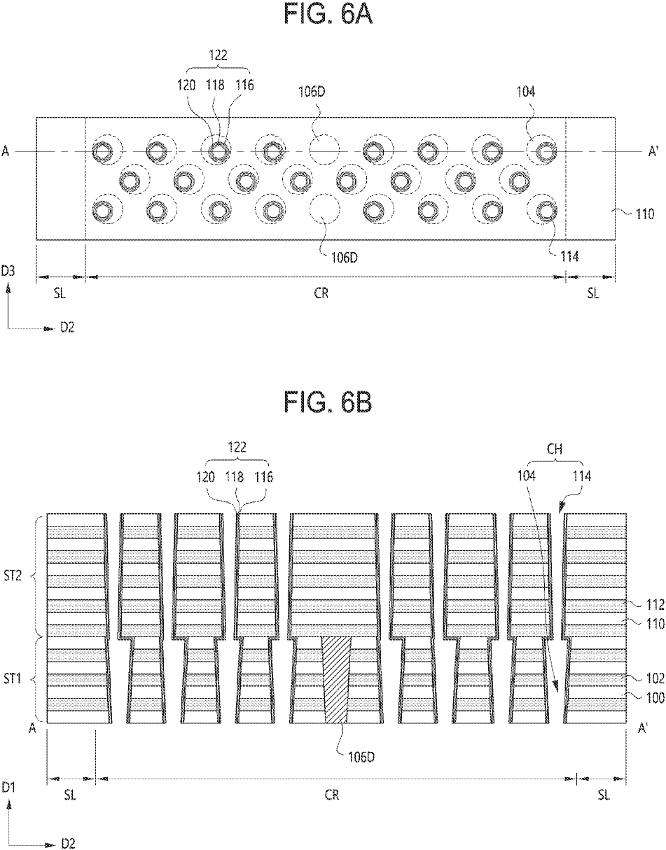

Referring to FIGS. 6A and 6B, a memory layer 122 may be conformally formed along a sidewall of the channel hole CH.

In various embodiments, a charge blocking layer 116, a data storage layer 118 and a tunnel insulation layer 120 may be sequentially formed along the sidewall of the channel hole CH to form the memory layer 122. The charge blocking layer 116 may include oxide for blocking charges. The data storage layer 118 may include nitride for trapping the charges. The tunnel insulation layer 120 may include oxide for a charge tunneling.

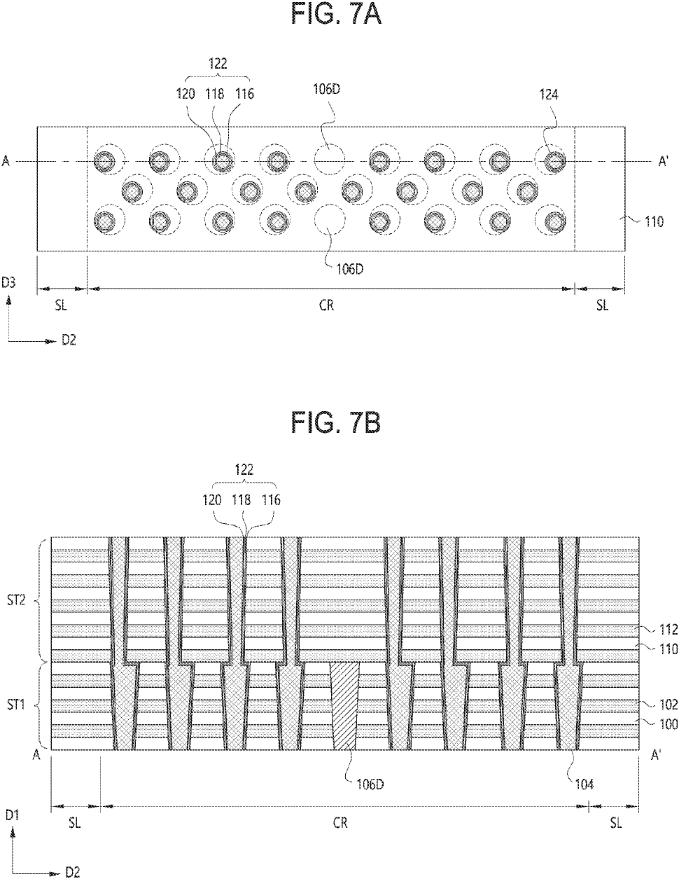

Referring to FIGS. 7A and 7B, the channel hole CH with the memory layer 122 may be filled with a channel layer 124 to form channel plugs CP.

In various embodiments, the channel layer 124 may include polysilicon, germanium, a semiconductor material having a nano-structure, etc. The channel layer 124 may be conformally formed on the sidewall of the channel hole CH where the memory layer 122 is formed. For example, the channel hole CH with the memory layer 122 and the channel layer 124 may be fully filled with a core layer C. The core layer C may include a buried insulation material.

A plurality of the channel plugs CP may be formed through the first sub stack ST1 and the second sub stack ST2 in the cell array region CR. The dummy plugs 106D may be formed through the first sub stack ST1 between the channel plugs CP.

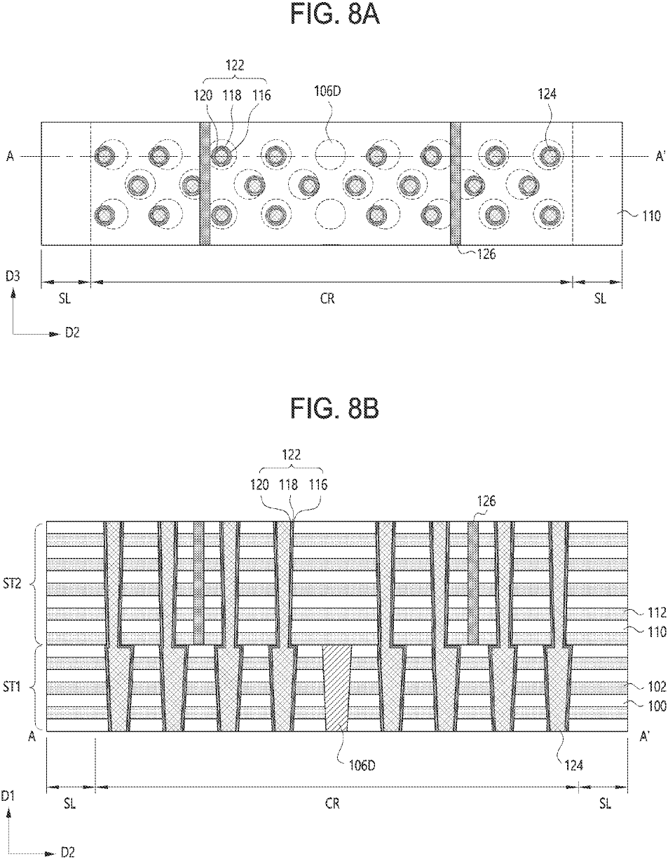

Referring to FIGS. 8A and 8B, the second sub stack ST2 in the cell array region CR may be etched to form first openings (not shown) extended in the third direction D3 in a plan view. The first openings may be configured to partially expose the first sub stack ST1. The first openings may cross between the channel plugs CP. However, the channel plugs CP might not be exposed through the first openings.

The first openings may be filled with an insulation material to form first separation patterns 126. The first separation patterns 126 may be arranged between the channel plugs CP in the second sub stack ST2.

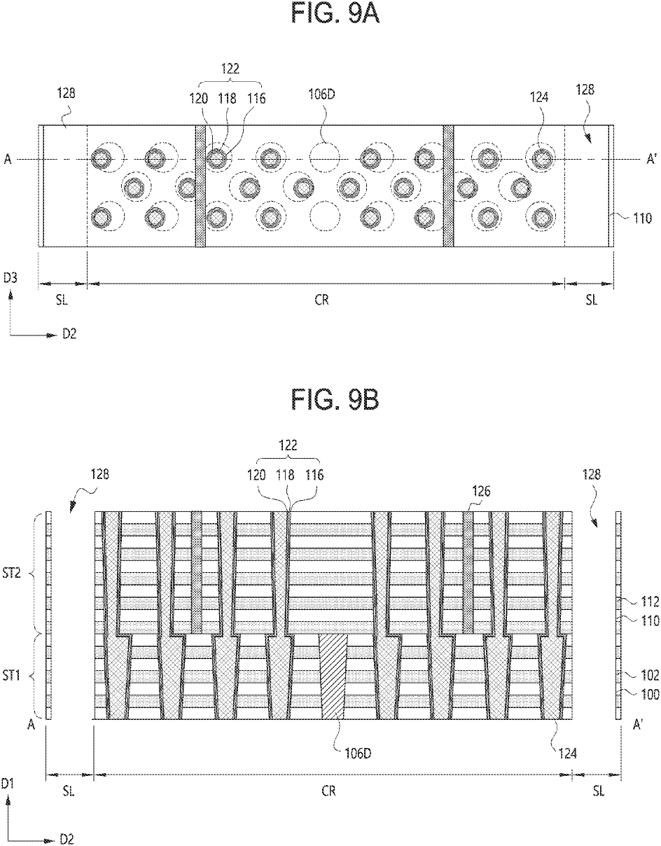

Referring to FIGS. 9A and 9B, the first sub stack ST1 and second sub stack ST2 may be etched to form a trench 128 in the slit region SL. The trench 128 may be configured to define the cell array regions CR corresponding to a memory block B. The trench 128 may be extended to the third direction in the plan view as shown in FIG. 9A. Further, the trench 128 may be extended to the first direction in the cross-sectional view as shown in FIG. 9B.

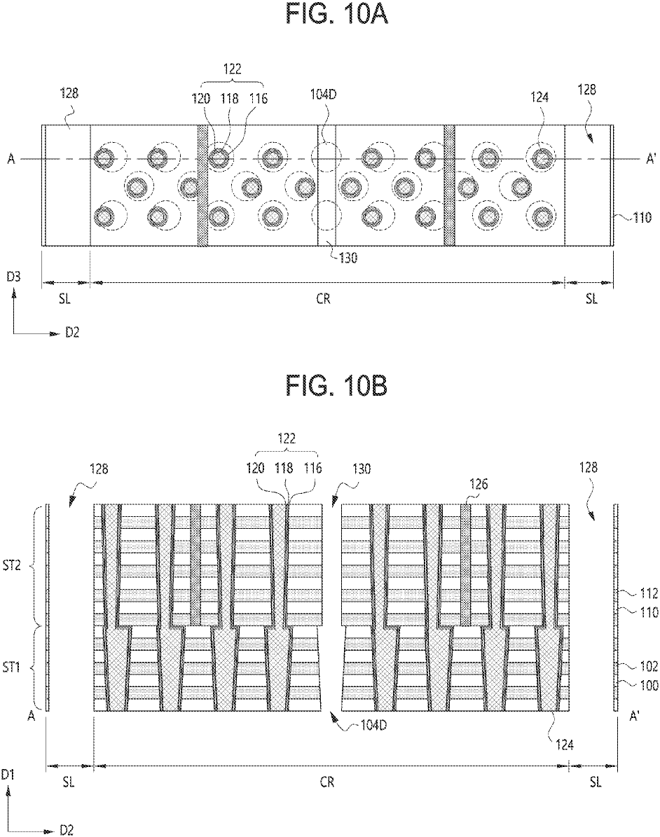

Referring to FIGS. 10A and 10B, the second sub stack ST2 in the cell array region CR may be etched to form a second opening 130 extended in a direction. The second opening 130 may be configured to expose the dummy plugs 106D. For example, the second opening 130 may be arranged between the channel plugs CP. Further, the second opening 130 may be positioned between the adjacent first separation patterns 126. The dummy plugs 106D arranged along the column direction may be exposed through the second opening 130, not limited thereto.

The dummy plugs 106D exposed through the second opening 130 may be selectively removed to define the dummy holes 104D in the first sub stack ST1. The first dummy holes 104D may be connected to the second opening 130.

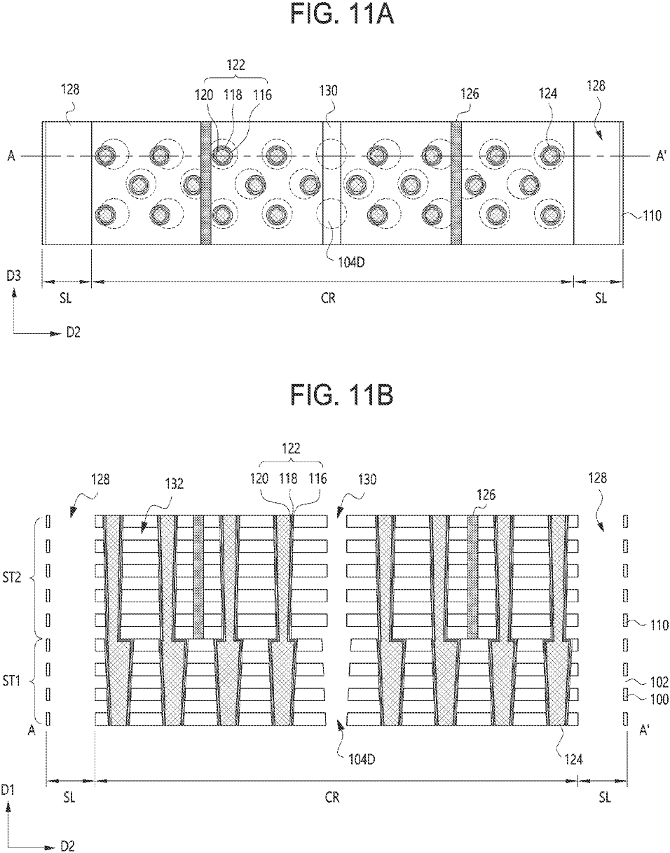

Referring to FIGS. 11A and 11B, the first sacrificial layers 102 and the second sacrificial layers 112 exposed through sidewalls of the trench 128, the second opening 130 and the dummy holes 104D may be etched to define a plurality of gaps 132 between the first insulation layers 100, between an uppermost first insulation layer 100 and a lowermost second insulation layer 110, and between the second insulation layers 110.

An etchant for etching the first and second sacrificial layers 102 and 112 may be moved through the second opening 130 and the dummy holes 104D as well as the trench 128 to readily and completely remove the first and second sacrificial layers 102 and 112. Thus, sizes of the plurality of gaps 132 for forming the gates having setting thicknesses may be secured.

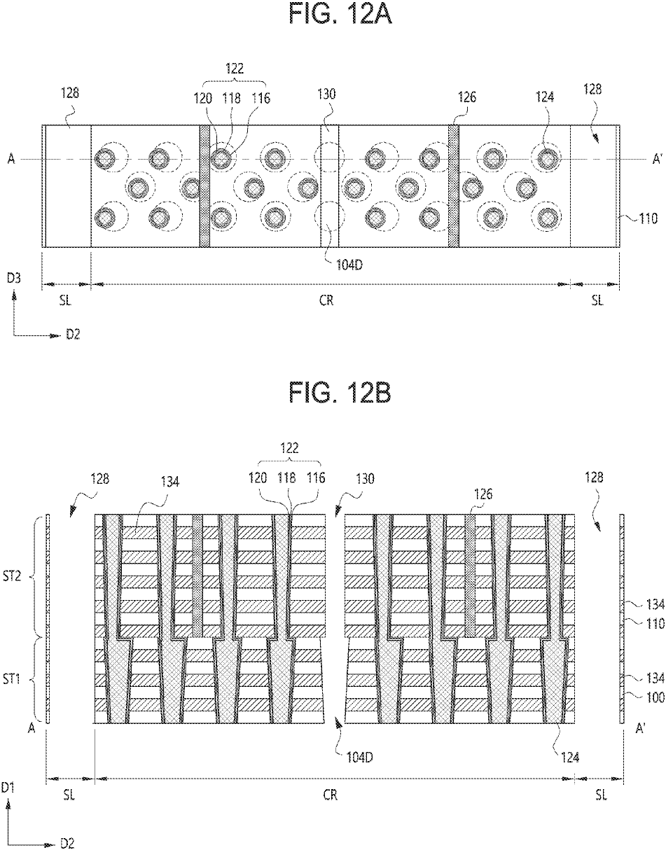

Referring to FIGS. 12A and 12B, the plurality of gaps 132 may be filled with a conductive material to form conductive patterns 134 as gate lines of the cell array region CR.

The conductive patterns 134 may be filled in the plurality of gaps 132 by the trench 128, the second opening 130 and the dummy holes 104D.

Referring again to FIGS. 1A and 1B, the second opening 130 and the dummy holes 104D may be filled with an insulation material to for a second separation pattern 138. For example, the second separation pattern 138 of the first sub stack ST1 may have a plug structure being similar with the first dummy plug 106D and the second separation pattern 138 of the second sub stack ST2 may have a line structure being similar with the first separation pattern 126.

The trench 128 in the slit region SL may be filled with an insulation material to form a slit structure 136. In various embodiments, the second separation pattern 138 may be formed together with the slit structure 136. Alternatively, after forming an insulation spacer in the trench 128, the trench 128 with the insulation spacer may be filled with a conductive material to form a source contact plug.

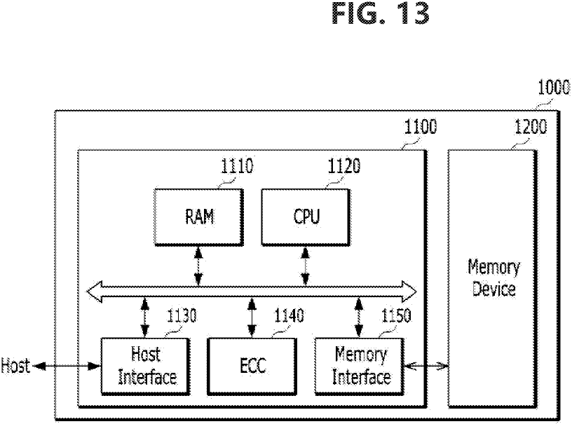

FIG. 13 is a block diagram illustrating a memory system in accordance with various embodiments,

Referring to FIG. 13, As illustrated in FIG. 13, the memory system 1000 may include a memory device 1200 and a controller 1100.

The memory device 1200 may be used to store various data types such as text, graphic and software code. The memory device 1200 may be a non-volatile memory with a PUC (peri under cell) structure or a volatile memory with a PUC structure. The memory device 1200 according to the various embodiments may provide gates of the memory cell array regions having a uniform thickness by forming of FIG. 1A to FIG. 12B.

The controller 1100 may be couple to a host and the memory device 1200, and may access the memory device 1200 in response to a request from the host. For example, the controller 1100 may control read, write, erase, and background operations of the memory device 1200.

The controller 1100 may include a random access memory (RAM) 1110, a central processing unit (CPU) 1120, a host interface 1130, an error correction code (ECC) circuit 1140, and a memory interface 1150.

The RAM 1110 may function as an operation memory of the CPU 1120, a cache memory between the memory device 1200 and the host, and a buffer memory between the memory device 1200 and the host. The RAM 1110 may be replaced by a static random access memory (SRAM) or a read only memory (ROM).

The host interface 1130 may be interface with the host. For example, the controller 1100 may communicate with the host through one of various interface protocols including a Universal Serial Bus (USB) protocol, a multimedia card (MMC) protocol, a peripheral component interconnection (PCI) protocol, a PCI express (PCI-E) protocol, an Advanced Technology Attachment (ATA) protocol, a Serial-ATA protocol, a Parallel-ATA protocol, a small computer small interface (SCSI) protocol, an enhanced small disk interface (ESDI) protocol, an Integrated Drive Electronics (IDE) protocol, and a private protocol.

The ECC circuit 1140 may detect and correct errors included in data read from the memory device 1200 by using error correction codes (ECCs).

The memory interface 1150 may interface with the memory device 1200. For example, the memory interface 1150 may include a NAND interface or a NOR interface.

For example, the controller 1100 may further include a buffer memory (not illustrated) configured to temporarily store data. The buffer memory may temporarily store data, externally transferred through the host interface 1130, or temporarily store data, transferred from the memory device 1200 through the memory interface 1150. In addition, the controller 1100 may further include ROM storing code data to interface with the host.

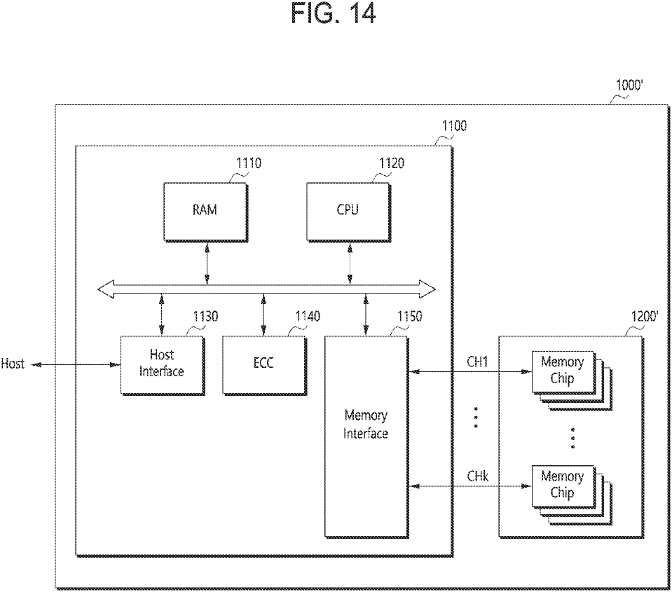

FIG. 14 is a block diagram illustrating a memory system in accordance with various embodiments,

Referring to FIG. 14, the memory system 1000′ may include a memory device 1200′ and the controller 1100. In addition, the controller 1100 may include the RAM 1110, the CPU 1120, the host interface 1130, the ECC circuit 1140, and the memory interface 1150.

In addition, the memory device 1200′ may be a multichip package composed of a plurality of memory chips. The plurality of memory chips may be divided into a plurality of groups. The plurality of groups may communicate with the controller 1100 through first to k-th channels CH1 to CHk. In addition, memory chips, included in a single group, may be suitable for communicating with the controller 1100 through a common channel. The memory system 1000′ may be modified so that a single memory chip may be coupled to a single channel. Referring to FIG. 14, a device 1200′ may include a non-volatile memory. As shown in FIGS. 1A to 12B, in an embodiment, the sacrificial layers may be completely removed through the dummy holes and the second opening for the second separation pattern to improve characteristics of a memory cell, thereby securing uniformity of the device 1200′.

According to various embodiments, an angular portion of the memory layer might not be formed to improve the characteristics of the memory cell, thereby securing the uniformity of the memory system 1000′.

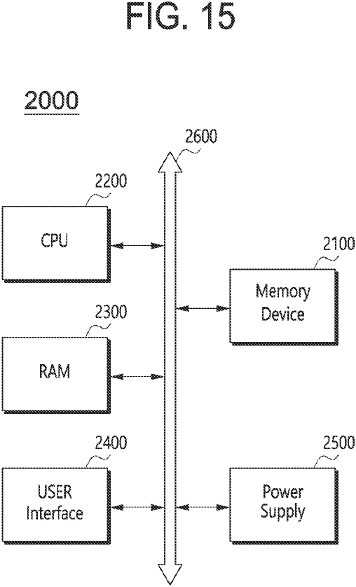

FIG. 15 is a block diagram illustrating a computing system in accordance with various embodiments.

As illustrated in FIG. 15, the computing system 2000 may include a memory device 2100, a CPU 2200, a random-access memory (RAM) 2300, a user interface 2400, a power supply 2500, and a system bus 2600.

The memory device 2100 may store data, which is input through the user interface 2400, and data, which is processed by the CPU 2200. In addition, the memory device 2100 may be electrically coupled to the CPU 2200, the RAM 2300, the user interface 2400, and the power supply 2500. For example, the memory device 2100 may be coupled to the system bus 2600 through a controller (not illustrated) or directly coupled to the system bus 2600. When the memory device 2100 is directly coupled to the system bus 2600, functions of the controller may be performed by the CPU 2200 and the RAM 2300.

The memory device 2100 may include a non-volatile memory. As shown in FIGS. 1A to 12B, in an embodiment, the sacrificial layers may be completely removed through the dummy holes and the second opening for the second separation pattern to improve characteristics of a memory cell, thereby securing uniformity of the device 2100. Further, the device 2100 may include a multichip package including the semiconductor devices of various embodiments.

According to various embodiments, the computing system 2000 may have an improved integration density of a word line to improve characteristics of the computing system 2000.

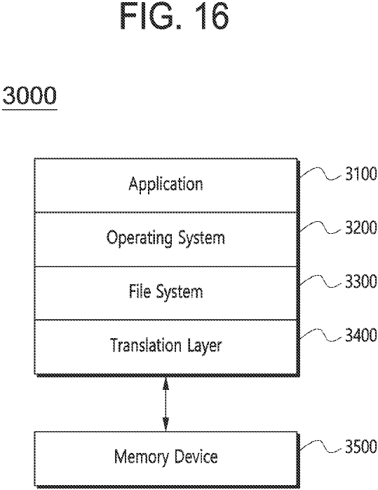

FIG. 16 is a block diagram illustrating a computing system in accordance with various embodiments.

As illustrated in FIG. 16, the computing system 3000 may include a software layer that has an operating system 3200 an application 3100, a file system 3300, and a translation layer 3400. In addition, the computing system 3000 may include a hardware layer such as a memory device 3500. In some embodiments, the computing system 3000 may include a hardware layer such as a memory system.

The operating system 3200 manages software and hardware resources of the computing system 3000. The operating system 3200 may control program execution of a central processing unit. The application 3100 may include various application programs executed by the computing system 3000. The application 3100 may be a utility executed by the operating system 3200.

The file system 3300 may refer to a logical structure configured to manage data and files present in the computing system 3000. The file system 3300 may organize files or data to be stored in the memory device 3500 according to rules. The file system 3300 may be determined depending on the operating system 3200 that is used in the computing system 3000. For example, when the operating system 3200 is a Microsoft Windows-based system, the file system 3300 may be a file allocation table (FAT) or an NT file system (NTFS). In addition, when the operating system 3200 is a Unix/Linux-based system, the file system 3300 may be an extended file system (EXT), a Unix file system (UFS), or a journaling file system (JFS).

The translation layer 3400 may translate an address to be suitable for the memory device 3500 in response to a request from the file system 3300. For example, the translation layer 3400 may translate a logic address, generated by the file system 3300, into a physical address of the memory device 3500. Mapping information of the logic address and the physical address may be stored in an address translation table. For example, the translation layer 3400 may be a flash translation layer (FTL), a universal flash storage link layer (ULL), or the like.

The memory device 3500 may include a non-volatile memory. As shown in FIGS. 1A to 12B, in an embodiment, the sacrificial layers may be completely removed through the dummy holes and the second opening for the second separation pattern to improve characteristics of a memory cell, thereby securing uniformity of the device 3500.

The computing system 3000 may be classified into an operating system class performed by a high-ranked level and an operating system class performed by a low-ranked level. The application 3100, the operating system 3200 and the file system 3300 may be included in the operating system class. The application 3100, the operating system 3200 and the file system 3300 may be driven by an operation memory of the computing system 3000. The translation layer 3400 may be included in the operating system class or a controller class.

According to various embodiments, the computing system 3000 may have improved integration density of a word line.

The above described embodiments of the present disclosure are intended to illustrate and not to limit the present disclosure. Various alternatives and equivalents are possible. The disclosure is not limited by the embodiments described herein. Nor is the disclosure limited to any specific type of semiconductor device. Another additions, subtractions, or modifications are obvious in view of the present disclosure and are intended to fall within the scope of the appended claims.

What is claimed is:

1. A three-dimensional (3D) semiconductor device comprising:
a memory block including at least one stack structure having at least one channel plug, the stack structure including a first sub stack and a second sub stack formed over the first sub stack; and
a separation pattern formed in the memory block, the separation pattern including at least one plug type insulation pattern positioned in the first sub stack and at least one of a bar type insulation pattern positioned in the second sub stack.

2. The 3D semiconductor device of claim 1,
wherein the separation pattern includes a plurality of the plug type insulation patterns,
wherein the plug type insulation patterns are spaced apart with a set interval in between, and
wherein each of the plug type insulation patterns are connected to the bar type insulation pattern.

3. The 3D semiconductor device of claim 1, wherein the first sub stack comprises at least one first conductive layer and at least one first insulation layer alternately stacked in a vertical direction, and
wherein the second sub stack comprises at least second conductive layer and at least one second insulation layer alternately stacked in the vertical direction.

4. The 3D semiconductor device of claim 3, wherein the channel plug includes:
a first portion formed in the first sub stack structure; and
a second portion connected to the first portion, and formed in the second sub stack.

5. The 3D semiconductor device of claim 4, wherein the second portion is at least partially overlapped with the first portion.

6. The 3D semiconductor device of claim 3, wherein the channel plugs are arranged in a matrix having n rows (n is a natural number greater than 2) and m columns (m is a natural number greater than 2), and
a channel plug in a (m-1)th column is arranged between an adjacent two channel plugs in a mth column.

7. The 3D semiconductor device of claim 3, wherein the bar type insulation pattern is arranged between an adjacent two channel plugs in a (k±1)th columns (1 <k<m, k is a natural number).

8. The 3D semiconductor device of claim 1, further comprising a slit structure formed at an edge of the memory block,
wherein the separation pattern is arranged between the slit structure, and
wherein the slit structure is substantially parallel to a column direction.

9. The 3D semiconductor device of claim 8, further comprising at least one additional separation pattern extended through the second sub stack,
wherein the additional separation pattern is positioned between the separation pattern and the slit structure.

10-15. (canceled)

16. A three-dimensional (3D) semiconductor device comprising:
a first sub stack including at least one first conductive layer and at least one first insulation layer alternately stacked in a vertical direction;
a second sub stack including at least one second conductive layer and at least one second insulation layer alternately stacked on the first sub stack in the vertical direction;
channel plugs formed through the first sub stack and the second sub stack;
at least one first separation pattern formed through the first sub stack, the first separation pattern having a cylindrical shape; and
a second separation pattern formed through the second sub stack, the second separation pattern having a bar shape, and the second separation pattern being contacted with the at least one first separation pattern.

17. The 3D semiconductor device of claim 16, wherein the first separation pattern is arranged between the channel plugs.
